(19) United States
(12) Patent Application Publication
(10) Pub. No.: US 2008/0105988 A1
(43) Pub. Date: May 8, 2008

(54) Electrical component having external contacting

(76) Inventor: Frieder Haag, Wannweil (DE)

Correspondence Address: KENYON & KENYON LLP, ONE BROADWAY, NEW YORK, NY, 10004, US

(21) Appl. No.: 11/980,151

(22) Filed: Oct. 29, 2007

(30) Foreign Application Priority Data
Oct. 30, 2006 (DE) 102006051199.9

(51) Int. Cl. H01L 23/49

(52) U.S. Cl. 257/784; 257/E23.024

(57) ABSTRACT

An electrical component includes at least one first semiconductor substrate, at least one contact means for the external contacting, and at least one bonding wire. The contact means has a first side and, diametrically opposite, a second side. The semiconductor substrate is situated on the first side of the contact means. The semiconductor substrate and the contact means are electrically conductively connected using the bonding wire and the bonding wire is connected to the contact means on the second side. A core idea is that the contact means has a recess on the second side and the bonding wire is connected to the contact means in the area of the recess.

### FIELD OF THE INVENTION

The present invention is directed to an electrical component having at least one first semiconductor substrate, at least one contact means for external contacting, and at least one bonding wire. The contact means has a first side and, diametrically opposite, a second side. The semiconductor substrate is situated on the first side of the contact means. The semiconductor substrate and the contact means are electrically connected using the bonding wire and the bonding wire is connected to the contact means on the second side.

### BACKGROUND INFORMATION

Typical electrical components having semiconductor elements such as microchips packaged by injection molding have a carrier strip having contact pins which project out of the envelope. The microchip is mounted having its bottom side on the top side of the carrier strip. Bonding wires run from the top side of the microchip to the top side of the contact pins and electrically connect the microchip to the contact pins.

Inertial sensors such as acceleration or speed sensors are typically capped in such a way that the mobile structures are protected. To be able to design housings thinner, there are embodiments in which the bottom housing half—the so-called QFN housing—is more or less dispensed with. For memory components, embodiments are known in which the contact pins are glued onto the chip surface and the bonding connections lie inside the surface of the silicon chip (known as lead-on-chip, LOC). Overall height is thus saved. Further constructions use the so-called flip-chip technology to fasten the microchip to the carrier strip (known as flip-chip on lead, FCOL). Due to the design that the bonding wires project above the height of the carrier strip, an LOC construction is not possible for a QFN housing. This is known in the related art only with SOIC housing forms.

### SUMMARY OF THE INVENTION

The present invention is directed to an electrical component having at least one first semiconductor substrate, at least one contact means for the external contacting, and at least one bonding wire. The contact means has a first side and, diametrically opposite, a second side. The semiconductor substrate is situated on the first side of the contact means. The semiconductor substrate and the contact means are electrically connected using the bonding wire and the bonding wire is connected on the second side to the contact means. A core of the present invention is that the contact means has a recess on the second side and the bonding wire is connected to the contact means in the area of the recess. The overall height of the entire electrical component is thus minimized.

In a particularly advantageous embodiment of the electrical component according to the present invention, the contact means has a contact surface on the second side for the external electrical contacting. It is also advantageous that the electrical component has at least one second semiconductor substrate, and the first semiconductor substrate is electrically connected to the second semiconductor substrate using at least one further bonding wire. It is advantageous that the electrical component has an envelope. It is particularly advantageous that the envelope envelops the contact means on the second side in the area of the recess and does not envelop the contact means in an area of the remaining second side, in particular in the area of the contact surface.

The present invention advantageously allows an LOC QFN housing to be provided, in that the terminal pins are made thinner in some areas. If the microchip is glued overhead onto the terminal pins (chip-on-lead), it is possible to bond to the thinned areas and to envelop them by extrusion coating, without the housing thus becoming thicker. The minimal possible overall height of the component is finally only determined by the height of the microchip and of the carrier strip or the terminal pins. A chip-on-lead construction is thus also possible for a QFN housing, without flip-chip technologies being necessary.

### BRIEF DESCRIPTION OF THE DRAWINGS

FIG. 1 schematically shows a first exemplary embodiment of an electrical component according to the present invention in a lateral sectional illustration.

FIG. 2 schematically shows a second exemplary embodiment of an electrical component according to the present invention in a top view.

### DETAILED DESCRIPTION

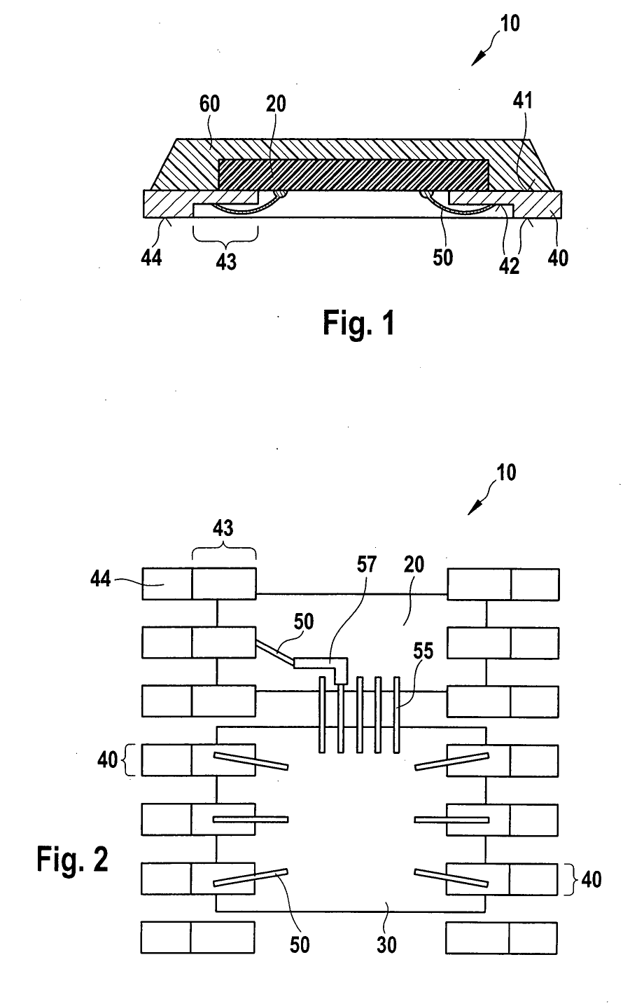

FIG. 1 schematically shows a first exemplary embodiment of an electrical component according to the present invention in a lateral sectional illustration. A component 10 according to the present invention is shown having a first semiconductor substrate 20, which is situated on a bottom side on first contact means 40 for external contacting, in this case terminal pins for external contacting. Contact means 40 has a first side 41 and, diametrically opposite, a second side 42. Semiconductor substrate 20 is situated having its bottom side on first side 41 of contact means 40. Semiconductor substrate 20 may be fastened to contact means 40 using a double-sided adhesive tape or another typical known fastener, which is not shown in greater detail here. Semiconductor substrate 20 and contact means 40 are electrically connected to one another using bonding wires 50. Bonding wire 50 is connected in each case at the bottom side of first semiconductor component 20 thereto and to contact means 40 on second side 42. An electrical connection from the semiconductor substrate to the terminal pin is thus produced.

According to the present invention, contact means 40 has a recess 43 on second side 42 and bonding wire 50 is connected to contact means 40 in the area of recess 43. The terminal pins are part of a carrier strip and are produced from copper by etching. The etching procedure takes place from both sides. It is thus possible to introduce steps into the carrier strip and/or into the terminal pins, which form cited recesses 43. Alternatively, such steps may also be produced by other known manufacturing methods, for example, by embossing a punched carrier strip (punched lattice). Recess 43 is only schematically shown in a rectangular shape in the figure. However, recess 43 may also have any other conceivable shape. It is important that bonding wire 50 may be contacted in the area of recess 43, and that recess 43 is designed in such a way that it minimizes the overall height produced by bonding wire 50.

FIG. 2 schematically shows a second exemplary embodiment of an electrical component according to the present invention in a top view. A component 10 according to the present invention is again shown. In addition to the elements already described in FIG. 1, a second semiconductor substrate 30 is provided here, which is situated next to first semiconductor substrate 20 on the carrier strip. First and second semiconductor substrates 20, 30 are electrically connected to one another on their bottom sides using further bonding wires 55. A conductor bar 57 is schematically shown on first semiconductor substrate 20, which is connected using a bonding wire 50 to a contact pin 40 in proximity to first semiconductor substrate 20. Conductor bar 57 is additionally connected using a further bonding wire 55 to second semiconductor substrate 30. In this way, electrical contacting from second semiconductor substrate 30 to a contact pin 40 may occur, which is situated relatively far away in an area of first semiconductor substrate 20.

A preferred embodiment of the present invention according to FIG. 2 is micromechanical sensors, in particular inertial sensors such as acceleration sensors or speed sensors, but also pressure sensors, inter alia. The micromechanical sensor is designed here as a 2-chip module, one semiconductor substrate having an application-specific integrated circuit (ASIC) and another semiconductor substrate having the actual micromechanical functional elements. Both substrates or chips are constructed next to one another in a shared housing. The surface of the micromechanical chip may even be used for a suitable configuration of contact surfaces or wire bonding connections and/or for conductor bars.

What is claimed is:

1. An electrical component comprising:
at least one contact element for external contacting, the contact element having a first side and, diametrically opposite, a second side, the contact element having a recess on the second side;
at least one first semiconductor substrate situated on the first side of the contact element; and
at least one bonding wire for electrically conductively connecting the first semiconductor substrate and the contact element, the bonding wire being connected to the contact element on the second side, the bonding wire being connected to the contact element in an area of the recess.

2. The electrical component according to claim 1, wherein the contact element has a contact surface on the second side for an external electrical contacting.

3. The electrical component according to claim 1, further comprising at least one second semiconductor substrate and at least one further bonding wire, and wherein the first semiconductor substrate is electrically conductively connected to the second semiconductor substrate using the at least one further bonding wire.

4. The electrical component according to claim 1, further comprising an envelope.

5. The electrical component according to claim 4, wherein the envelope envelops the contact element on the second side in the area of the recess and does not envelop the contact element in at least one area of a remaining second side.

6. The electrical component according to claim 5, wherein the envelope does not envelop the contact element in an area of a contact surface.
